(19) United States
(12) Patent Application Publication
(10) Pub. No.: US 2026/0136655 A1
(43) Pub. Date: May 14, 2026

(54) GATE-ALL-AROUND FIELD EFFECT TRANSISTOR STRUCTURE

(71) Applicant: ELECTRONICS AND TELECOMMUNICATIONS RESEARCH INSTITUTE, Daejeon (KR)

(72) Inventors: Jeong Woo Park, Daejeon (KR); Dongwoo Suh, Daejeon (KR); Sang Hoon Kim, Daejeon (KR); Wangjoo Lee, Daejeon (KR); Seong Hyun Lee, Daejeon (KR)

(21) Appl. No.: 19/379,240

(22) Filed: Nov. 4, 2025

(30) Foreign Application Priority Data
Nov. 12, 2024 (KR) 10-2024-0160242
Oct. 30, 2025 (KR) 10-2025-0160247

(51) Int. Cl. H10D 84/85

(52) U.S. Cl. CPC H10D 84/851; H10D 84/856

(57) ABSTRACT

A complementary gate-all-around field effect transistor (GAA-FET) structure is provided. The complementary GAA-FET structure includes a substrate, a shallow trench isolation (STI) structure formed on the substrate, and a pair of p-type GAA-FET and n-type GAA-FET stacked in a vertical direction in an active region defined by the STI structure. A gate metal layer of the p-type GAA-FET and a gate metal layer of the n-type GAA-FET have the same structure.

### CROSS-REFERENCE TO RELATED APPLICATIONS

This application claims the benefit of the Korean Patent Application No. 10-2024-0160242 filed on Nov. 12, 2024, and Korean Patent Application No. 10-2025-0160247 filed on Oct. 30, 2025, which is hereby incorporated by reference as if fully set forth herein.

### BACKGROUND

### 1. Field of the Invention

The present disclosure relates to a gate-all-around field effect transistor (hereinafter referred to as a GAA-FET) structure, and more particularly, to a GAA-FET structure including an n-type GAA-FET and a p-type GAA-FET.

### 2. Description of Related Art

As semiconductor devices are highly integrated, the size of transistors has been progressively reduced, and thus, a distance (i.e., a channel length) between a drain and a source has been shortened. However, as channels are progressively shortened, the electric field control capability of gates is reduced, and due to this, a problem has occurred where the short channel effect (SCE) where a turn-on/off characteristic is degraded is deteriorated.

Fin field effect transistors (FinFETs) have been introduced for alleviating the SCE. FinFETs have a structure where a gate surrounds three sides (for example, left, right, and upper sides) of a fin-type channel and may more enhance gate control capability than conventional metal oxide semiconductor field effect transistors (MOSFETs), and thus, may effectively prevent the SCE. However, process miniaturization has entered the level of 3 nano or less, and thus, in a FinFET structure, as channels are thinned by atom units, physical limitations such as the limitation of gate control and an increase in a leakage current have occurred.

A GAA-FET structure has been proposed as next-generation technology for overcoming the limitations described above. GAA-FETs may fully surround four sides (for example, upper, lower, left, and right sides) of a channel and may control the channel, and thus, may fundamentally prevent the SCE.

Recently, a GAA-FET structure where an n-type GAA-FET and a p-type GAA-FET are arranged in a horizontal direction and a complementary GAA-FET structure where an n-type GAA-FET and a p-type GAA-FET are stacked in a vertical direction has been proposed based on GAA-FET technology.

However, n-type and p-type GAA-FETs need different manufacturing conditions in a channel material, a doping concentration, a formation temperature, and a gate formation order, and due to this, process interference or an alignment mismatch easily occurs when implementing two devices in the same chip. Particularly, in the complementary GAA-FET structure, the complexity of channel formation and a gate deposition order has more increased in a vertical stack process, and due to this, the controllability margin of an entire process has been reduced.

As described above, due to a manufacturing condition difference between n-type and p-type GAA-FETs, a problem has occurred where a process step is complicated, and the controllability margin of a manufacturing process is reduced, and due to this, the conventional GAA-FET structure and the complementary GAA-FET structure have a limitation where mass productivity is disadvantage compared to a complementary metal oxide semiconductor (CMOS) process.

The above-described background is possessed by the inventor of the application for deriving the disclosure, or is technology information that has been acquired in deriving the disclosure. The above-described background is not necessarily known technology disclosed to the general public before the application of the disclosure.

### SUMMARY

An aspect of the present disclosure is directed to providing a complementary GAA-FET in which a gate structure of an n-type GAA-FET and a gate structure of a p-type GAA-FET are configured to be equal to each other, in the complementary GAA-FET where the n-type GAA-FET and the p-type GAA-FET are arranged in a horizontal direction or are stacked in a vertical direction.

The objects of the present disclosure are not limited to the aforesaid, but other objects not described herein will be clearly understood by those skilled in the art from descriptions below.

To achieve these and other advantages and in accordance with the purpose of the invention, as embodied and broadly described herein, there is provided a complementary gate-all-around field effect transistor (GAA-FET) structure including a substrate, a shallow trench isolation (STI) structure formed on the substrate, and a pair of p-type GAA-FET and n-type GAA-FET stacked in a vertical direction in an active region defined by the STI structure, wherein a gate metal layer of the p-type GAA-FET and a gate metal layer of the n-type GAA-FET have the same structure.

In an embodiment, the gate metal layer of the p-type GAA-FET and the gate metal layer of the n-type GAA-FET may be formed by using the same material to have the same gate length and the same gate width.

In an embodiment, the gate metal layer of the p-type GAA-FET and the gate metal layer of the n-type GAA-FET may be formed by using one or more of metals or metal compounds such as titanium nitride (TiN), titanium aluminum carbide (TiAlC), titanium aluminum nitride (TiAlN), titanium carbide (TiC), tungsten (W), titanium, (Ti), tantalum (Ta), molybdenum (Mo), and cobalt (Co).

In an embodiment, each of the p-type GAA-FET and the n-type GAA-FET may include a plurality of semiconductor channel layers, the gate metal layer surrounding a corresponding semiconductor channel layer among the plurality of semiconductor channel layers, and a gate dielectric layer disposed between the corresponding semiconductor channel layer and the gate metal layer, and the gate dielectric layer of the p-type GAA-FET and the gate dielectric layer of the n-type GAA-FET may be formed in the same structure.

In an embodiment, the gate dielectric layer of the p-type GAA-FET and the gate dielectric layer of the n-type GAA-FET may be formed by using the same material to have the same thickness.

In an embodiment, each of the gate dielectric layer of the p-type GAA-FET and the gate dielectric layer of the n-type GAA-FET may include a silicon oxide layer surrounding a corresponding semiconductor channel layer and a high-k dielectric layer surrounding the silicon oxide layer.

In an embodiment, the high-k dielectric layer may be formed by using one or more of aluminum oxide (Al₂O₃), hafnium oxide (HfO₂), zirconium oxide (ZrO₂), hafnium zirconium oxide (HfZrO₄), titanium oxide (TiO₂), scandium oxide (Sc₂O₃), yttrium oxide (Y₂O₃), lanthanum oxide (La₂O₃), lutetium oxide (Lu₂O₃), niobium oxide (Nb₂O₅), and tantalum oxide (Ta₂O₅).

In an embodiment, the complementary GAA-FET structure may further include another pair of p-type GAA-FET and n-type GAA-FET stacked in the vertical direction, wherein gate structures of the other pair of p-type GAA-FET and n-type GAA-FET may be formed to be equal to each other, and gate structures of the pair of p-type GAA-FET and n-type GAA-FET and the gate structures of the other pair of p-type GAA-FET and n-type GAA-FET may be formed to be different from each other.

In another aspect of the present invention, there is provided a complementary gate-all-around field effect transistor (GAA-FET) structure including a substrate, a shallow trench isolation (STI) structure formed on the substrate, and a pair of p-type GAA-FET and n-type GAA-FET disposed in a horizontal direction in an active region defined by the STI structure, wherein a gate metal layer of the p-type GAA-FET and a gate metal layer of the n-type GAA-FET have the same structure.

In an embodiment, the gate metal layer of the p-type GAA-FET and the gate metal layer of the n-type GAA-FET may be formed by using the same material to have the same gate length and the same gate width.

In an embodiment, each of the p-type GAA-FET and the n-type GAA-FET may include a plurality of semiconductor channel layers, the gate metal layer surrounding a corresponding semiconductor channel layer among the plurality of semiconductor channel layers, and a gate dielectric layer disposed between the corresponding semiconductor channel layer and the gate metal layer, and the gate dielectric layer of the p-type GAA-FET and the gate dielectric layer of the n-type GAA-FET may be formed in the same structure.

In an embodiment, the gate dielectric layer of the p-type GAA-FET and the gate dielectric layer of the n-type GAA-FET may be formed by using the same material to have the same thickness.

In an embodiment, each of the gate dielectric layer of the p-type GAA-FET and the gate dielectric layer of the n-type GAA-FET may include a silicon oxide layer surrounding a corresponding semiconductor channel layer and a high-k dielectric layer surrounding the silicon oxide layer.

In an embodiment, the complementary GAA-FET structure may further include another pair of p-type GAA-FET and n-type GAA-FET disposed in the horizontal direction, wherein gate structures of the other pair of p-type GAA-FET and n-type GAA-FET may be formed to be equal to each other, and gate structures of the pair of p-type GAA-FET and n-type GAA-FET and the gate structures of the other pair of p-type GAA-FET and n-type GAA-FET may be formed to be different from each other.

According to embodiments of the present disclosure, in a GAA-FET where an n-type GAA-FET and a p-type GAA-FET are arranged in a horizontal direction, or a complementary GAA-FET where the n-type GAA-FET and the p-type GAA-FET are stacked in a vertical direction, a gate structure of the n-type GAA-FET and a gate structure of the p-type GAA-FET (for example, a gate insulator structure and a gate metal structure) may be configured to be equal to each other, and thus, a process may be simplified, and a layout may be simplified, thereby improving mass productivity.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1 is a schematic perspective view of a complementary GAA-FET structure according to an embodiment of the present disclosure.

FIG. 2 is a cross-sectional view of the complementary GAA-FET structure of FIG. 1.

FIG. 3 is a graph illustrating a threshold voltage Vt characteristic of n-type and p-type GAA-FETs where structures of gate dielectric layers are equal to each other and structures of gate metal layers differ, in a complementary GAA-FET structure according to an embodiment of the present disclosure.

FIG. 4 is a graph illustrating a current (Ion and Ioff) characteristic of n-type and p-type GAA-FETs where structures of gate dielectric layers are equal to each other and structures of gate metal layers differ, in a complementary GAA-FET structure according to an embodiment of the present disclosure.

FIG. 5 is a schematic perspective view of a complementary GAA-FET structure according to another embodiment of the present disclosure.

FIG. 6 is a cross-sectional view of the complementary GAA-FET structure of FIG. 5.

### DETAILED DESCRIPTION OF THE INVENTION

Reference will now be made in detail to the exemplary embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims. In the following description, the technical terms are used only for explaining a specific embodiment while not limiting the present disclosure.

Herein, when an arbitrary material film such as a layer or a film is described as being “on” another material film or a substrate, this may denote that the arbitrary material film may be directly formed on the other material film or the substrate, or another material film may be disposed therebetween.

In various embodiments of the present disclosure, the terms “first, second, and third” may be used for describing a material film or a process step, but may be merely used for distinguishing a specific material film or a specific process step from another material film or another process step and the present disclosure is not limited by the terms.

The terms used herein are for the purpose of describing particular embodiments only and are not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Moreover, embodiments described herein may be described with reference to an ideal perspective view and/or cross-sectional views of the present disclosure. In the drawings, thicknesses of layers and regions may be exaggerated for the effective description of technical content. Therefore, the form of an exemplary diagram may be modified by manufacturing technology and/or an allowable error. Accordingly, embodiments of the present disclosure are not limited to an illustrated specific form and may include the modification of a shape generated based on a manufacturing process. For example, a rectangularly illustrated etch region may have a shape which is rounded or has a certain curvature. Regions illustrated in the drawings may have a schematic attribute, and shapes of the regions illustrated in the drawings are for illustrating a specific shape of a region of an element and are not for limiting the scope of the present disclosure.

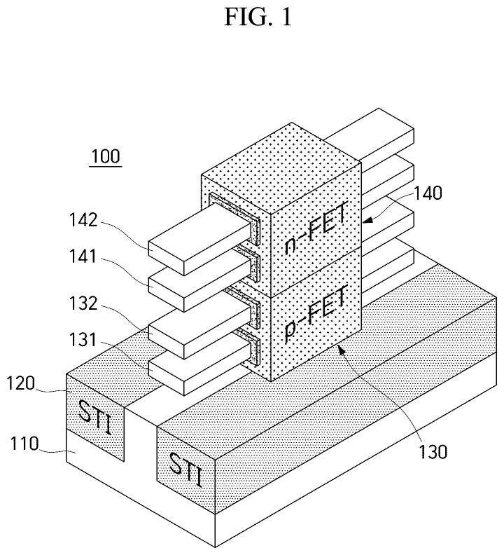

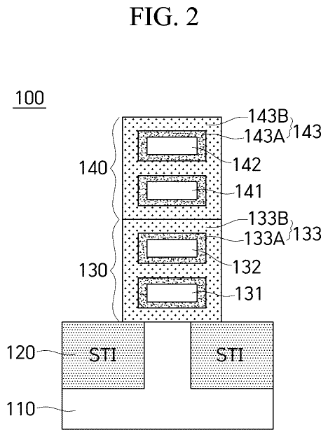

FIG. 1 is a schematic perspective view of a complementary GAA-FET structure 100 according to an embodiment of the present disclosure, and FIG. 2 is a cross-sectional view of the complementary GAA-FET structure 100 of FIG. 1.

Referring to FIGS. 1 and 2, the complementary GAA-FET structure 100 according to an embodiment of the present disclosure may include a substrate 110, a shallow trench isolation (STI) structure 120 formed on the substrate 110, and a p-type GAA-FET (p-FET) 130 and an n-type GAA-FET (n-FET) 140 formed in an active region defined by the STI structure 120.

The substrate 110 may include, for example, a silicon wafer (Si wafer).

The STI structure 120, for example, may be formed of silicon dioxide (SiO₂) and may define the active region. The active region may be a semiconductor region where a channel, through which a current flows actually, is formed on the substrate 110 and may denote a substrate region or a silicon wafer region exposed upward between adjacent STI structures 120.

The p-type GAA-FET 130 and the n-type GAA-FET 140 may be stacked in a vertical direction in the active region. The p-type GAA-FET 130 and the n-type GAA-FET 140 stacked in the vertical direction may be electrically insulated from adjacent elements by the STI structure 120.

In FIGS. 1 and 2, a case where the n-type GAA-FET 140 is stacked on the p-type GAA-FET 130 is illustrated, but contrariwise, the p-type GAA-FET 130 may be stacked on the n-type GAA-FET 140.

The p-type GAA-FET 130 may include a plurality of semiconductor channel layers 131 and 132 and a gate structure 133 which surrounds all sides of each of the semiconductor channel layers 131 and 132. Similarly, the n-type GAA-FET 140 may include a plurality of semiconductor channel layers 141 and 142 and a gate structure 143 which surrounds all sides of each of the semiconductor channel layers 141 and 142. Here, each semiconductor channel layer may be formed in a nanosheet form or a nanowire form.

The gate structure 133 of the p-type GAA-FET 130 may include a gate metal layer 133B which surrounds all sides of each semiconductor channel layer and a gate dielectric layer 133A disposed between each semiconductor channel layer 132 and the gate metal layer 133B.

The gist of the complementary GAA-FET structure 100 according to the present embodiment may be characterized in that the gate structure 133 of the p-type GAA-FET 130 and the gate structure 143 of the n-type GAA-FET 140 are formed to be equal to each other. That is, in the complementary GAA-FET structure 100 according to the present embodiment, the gate metal layer 133B of the p-type GAA-FET 130 and a gate metal layer 143B of the n-type GAA-FET 140 may have the same structure, and optionally, the gate dielectric layer 133A of the p-type GAA-FET 130 and a gate dielectric layer 143A of the n-type GAA-FET 140 may have the same structure, and only a polarity of a source and a polarity of a drain (n type or p type) may differ.

In the p-type GAA-FET 130 and the n-type GAA-FET 140, the gate dielectric layers 133A and 143A formed in the same structure may be disposed between the semiconductor channel layer and the gate metal layer and may function as a layer which transfers a gate voltage to a corresponding semiconductor channel layer and prevents a leakage current.

Each of the gate dielectric layers 133A and 143A may include a silicon oxide layer surrounding a corresponding semiconductor channel layer and a high-k dielectric layer surrounding the silicon oxide layer.

The silicon oxide layer, for example, may be formed of SiO₂ or silicon oxynitride (SiON).

The high-k dielectric layer, for example, may be formed of one or more of aluminum oxide (Al₂O₃), hafnium oxide (HfO₂), zirconium oxide (ZrO₂), hafnium zirconium oxide (HfZrO₄), titanium oxide (TiO₂), scandium oxide (Sc₂O₃), yttrium oxide (Y₂O₃), lanthanum oxide (La₂O₃), lutetium oxide (Lu₂O₃), niobium oxide (Nb₂O₅), and tantalum oxide (Ta₂O₅).

In the p-type GAA-FET 130 and the n-type GAA-FET 140, each of the gate metal layers 133B and 143B formed in the same structure may include a work function metal layer (hereinafter referred to as a ‘WFM’) formed on the high-k dielectric layer and a fill metal layer formed on the WFM, and moreover, may further include a cap metal layer formed on the fill metal layer.

The WFM may be a layer which directly contacts the high-k dielectric layer and may be a layer which determines an effective work function of each of the gate metal layers 133B and 143B, and moreover, may largest affect an electrical characteristic (for example, a threshold voltage Vₜₕ, etc.) of a GAA-FET.

The WFM, for example, may be formed of one or more of metals or metal compounds such as titanium nitride (TiN), titanium aluminum carbide (TiAlC), titanium aluminum nitride (TiAlN), titanium carbide (TiC), tungsten (W), titanium, (Ti), tantalum (Ta), molybdenum (Mo), and cobalt (Co). However, the present disclosure is not limited thereto, and transition metal-based or alloy materials suitable for the adjustment of a threshold voltage may be used. The fill metal layer may be a layer which fills an internal void of a gate trench or secures mechanical strength and connects an upper wiring. The fill metal layer, for example, may be formed of one or more of metals such as W, Co, and Mo.

As described above, because the gate metal layer of the p-type GAA-FET 130 and the gate metal layer of the n-type GAA-FET 140 have the same structure, and the gate dielectric layer of the p-type GAA-FET 130 and the gate dielectric layer of the n-type GAA-FET 140 have the same structure, two elements may operate based on the same gate stack. Here, the same structure may denote that a thickness and a material of the gate dielectric layer of the p-type GAA-FET 130 are the same as those of the gate dielectric layer of the n-type GAA-FET 140, and a gate width, a gate length, and a material of the gate metal layer of the p-type GAA-FET 130 are the same as those of the gate metal layer of the n-type GAA-FET 140. In this case, the gate width may denote a width of a channel, namely, a length of a widthwise direction in which a current flows, and the gate length may denote a length of a gate (i.e., a channel length) disposed between a source and a drain.

In the complementary GAA-FET structure 100 according to an embodiment of the present disclosure, because the p-type GAA-FET 130 and the n-type GAA-FET 140 are stacked in the vertical direction, area efficiency may be enhanced compared to a conventional planar CMOS structure, and the degree of integration of devices may be maximized. Also, because a gate surrounds all sides of a channel, a channel leakage current may be prevented, and a short channel effect may be fundamentally alleviated.

Above all, in the p-type GAA-FET 130 and the n-type GAA-FET 140, only polarities may differ based on a doping concentration or a stress condition, and moreover, because the structures of the gate dielectric layers are configured to be equal to each other, the structures of the gate metal layers are configured to be equal to each other, the symmetricity of electrical characteristics of the p-type GAA-FET 130 and the n-type GAA-FET 140 may be secured, a process may be simplified, and a layout may be simplified, thereby improving mass productivity.

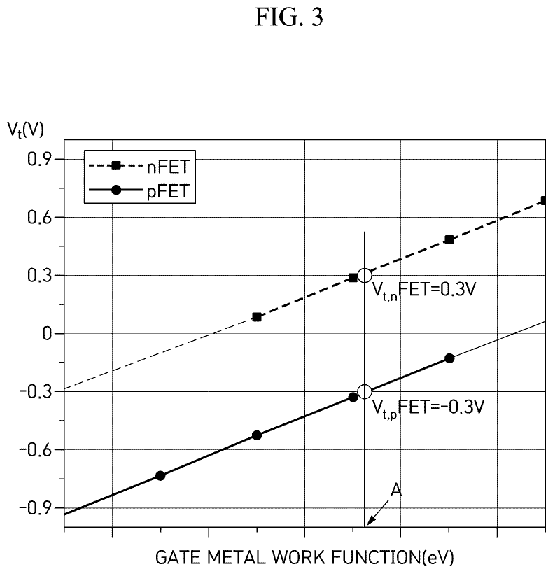

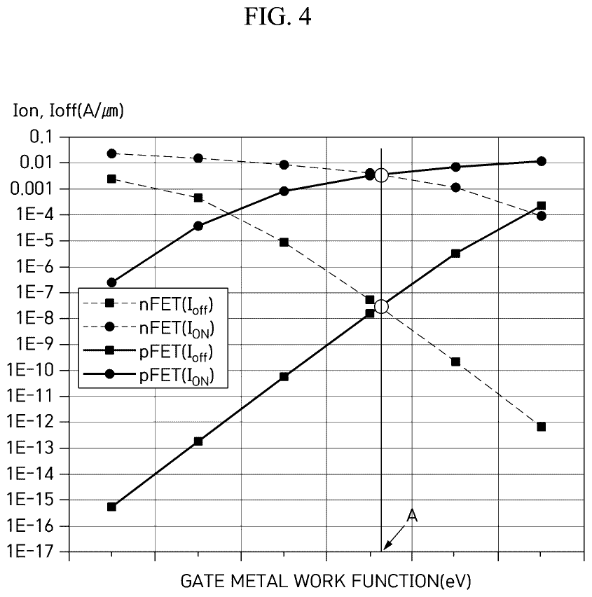

FIG. 3 is a graph illustrating a threshold voltage Vt characteristic of n-type and p-type GAA-FETs where the structures of the gate dielectric layers are equal to each other and the structures of the gate metal layers (for example, the WFM) differ, in the complementary GAA-FET structure according to an embodiment of the present disclosure. FIG. 4 is a graph illustrating a current (Ion and Ioff) characteristic of n-type and p-type GAA-FETs where the structures of the gate dielectric layers (for example, a gate oxide film) are equal to each other and the structures of the gate metal layers (for example, the WFM) differ, in the complementary GAA-FET structure according to an embodiment of the present disclosure.

In two graphs of FIGS. 3 and 4, the x axis represents a work function of the gate metal layer, and a point A represents a point at which threshold voltage absolute values |Vt| of the n-type GAA-FET (nFET) and the p-type GAA-FET (pFET) are equal to each other, and current characteristics or current densities Ion and Ioff of two transistors match each other. That is, at the point A, it may be seen that the n-type GAA-FET (nFET) and the p-type GAA-FET (pFET) are designed to have an electrically symmetrical characteristic.

The symmetry of threshold voltages Vt may assign symmetry to a static transfer curve of a logic gate or a logic circuit, and moreover, when the current densities Ion and Ioff of the n-type GAA-FET (nFET) and the p-type GAA-FET (pFET) are equal to each other, a dynamic operation (rise time and fall time) on a time axis may be performed to be symmetrical. Therefore, the on/off timing symmetry of a circuit may be maintained even after undergoing logic circuits of a plurality of stages, and thus, a time-axis operation window of the logic circuit may enlarge to enable a stable operation in a clock period, and an operation speed of an entire circuit may be enhanced.

In the related art, in order to secure the symmetry of a current, it may be designed that a gate width of the p-type GAA-FET (pFET) is greater than that of the n-type GAA-FET (nFET), and due to this, there may be a problem where layout efficiency is reduced, and a reduction in a chip area is unfavorable.

On the other hand, as in the complementary GAA-FET structure according to an embodiment of the present disclosure, when the n-type GAA-FET (nFET) and the p-type GAA-FET (pFET) are designed to have the same width, the same pattern may be repeated, and thus, the efficiency of a manufacturing process such as the simplification of a photo process and uniformity enhancement may increase.

Furthermore, in FIGS. 3 and 4, the x axis represents the work function of the gate metal layer (for example, the WFM), but this may be for a simple description and a characteristic of a real device may be complexly affected by a material and a thickness of the gate metal layer (for example, the WFM) and the configuration modification of the gate dielectric layer structure as well as the work function of the gate metal layer (for example, the WFM). Accordingly, as the gate dielectric layer structure is adjusted, it may be possible to control characteristics such as Vt, Ion, and Ioff.

According to an embodiment, as described above, the gate dielectric layer may be configured with a silicon oxide layer formed on the semiconductor channel layer and a high-k dielectric layer formed thereon, and by adjusting a thickness thereof, the |Vt|, Ion, and Ioff of the n-type GAA-FET (nFET) and the p-type GAA-FET (pFET) may be adjusted. Also, a device characteristic may vary based on the kind of gate metal layer (for example, WFM).

Moreover, as described above, the n-type GAA-FET (nFET) and the p-type GAA-FET (pFET) may be configured to have the same gate stack structure, and in addition to an nFET/pFET pair (pair 1) having the symmetrical characteristic of Vt, Ion, and Ioff, another pair (pair 2) having different |Vt|, Ion, and Ioff may be needed for the same substrate. In this case, the n-type GAA-FET (nFET) and the p-type GAA-FET (pFET) may have the same gate stack structure, but a gate stack structure which differs from the pair 1 may be applied thereto.

For example, a gate dielectric layer of the pair 2 may use a high-k dielectric layer which differs from the kind of high-k dielectric layer of the pair 1, or after the high-k dielectric layer is formed, different dipole-containing materials may be deposited, and annealing may be performed thereon, and thus, a gate dielectric layer where each pair has different electrical characteristics may be formed. In this case, the dipole-containing material may use La, Y, Al, Sr, Er, Se, and Nb, and moreover, may use a combination of one or more elements.

As described above, a gate stack structure of a pair of n-type GAA-FET (nFET) and p-type GAA-FET (pFET) may be applied to be different from a gate stack structure of another pair of n-type GAA-FET (nFET) and p-type GAA-FET (pFET). Accordingly, a plurality of transistor pairs which have different electrical characteristics and secure a symmetrical operation characteristic may be implemented in one wafer.

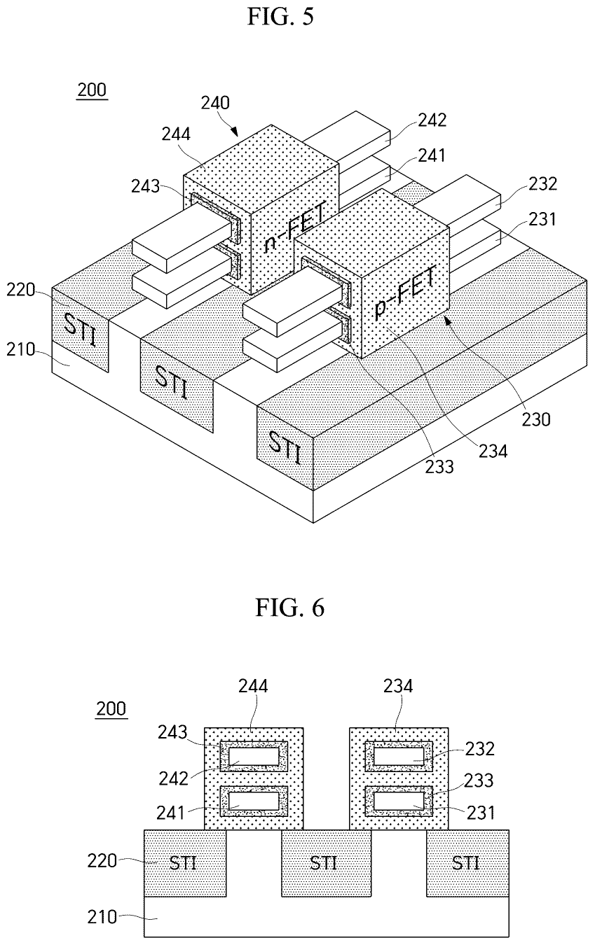

FIG. 5 is a schematic perspective view of a complementary GAA-FET structure 200 according to another embodiment of the present disclosure, and FIG. 6 is a cross-sectional view of the complementary GAA-FET structure 200 of FIG. 5.

Referring to FIGS. 5 and 6, the complementary GAA-FET structure 200 according to another embodiment of the present disclosure may include a substrate 210, an STI structure 220 formed on the substrate 210, and a p-type GAA-FET (p-FET) 230 and an n-type GAA-FET (n-FET) 240 formed in an active region defined by the STI structure 220.

The substrate 210 may include, for example, a silicon wafer (Si wafer), and the STI structure 220, for example, may be formed of SiO₂ and may electrically insulate the active region. The active region may be a region where a semiconductor channel, through which a current flows actually, is formed on the substrate 210 and may denote a substrate region or a silicon wafer region exposed upward between adjacent STI structures 220.

The complementary GAA-FET structure 200 according to another embodiment of the present disclosure, unlike the embodiment of FIGS. 1 and 2, may be characterized in that the p-type GAA-FET (p-FET) 230 and the n-type GAA-FET (n-FET) 240 are not stacked in a vertical direction and are arranged in parallel in a horizontal direction, on the substrate 210.

As in the embodiment of FIGS. 1 and 2, the p-type GAA-FET 230 and the n-type GAA-FET 240 may have the same gate structure. That is, the gate stack structure may be identically formed, and for example, widths W, lengths L, and materials of gate metal layers 234 and 244 may be formed to be equal to each other, thicknesses and materials of gate dielectric layers 233 and 243 may be formed to be equal to each other. Accordingly, in two elements, only a polarity of a source and a polarity of a drain (n type or p type) may differ, and a structural characteristic may be equal to each other.

The p-type GAA-FET 230 may include a plurality of semiconductor channel layers 231 and 232 and a gate dielectric layer 233 and a gate metal layer 234 which surround all sides of each of the semiconductor channel layers 231 and 232. Similarly, the n-type GAA-FET 240 may include a plurality of semiconductor channel layers 241 and 242 and a gate structure configured to include a gate dielectric layer 243 and a gate metal layer 244 which surround all sides of each of the semiconductor channel layers 241 and 242.

The gate dielectric layers 233 and 243 may be a layer which is disposed between the semiconductor channel layer and the gate metal layer, transfers a gate voltage, and prevents a leakage current. For example, the gate dielectric layers 233 and 243 may include a gate oxide layer and a high-k dielectric layer formed thereon.

The high-k dielectric layer may be formed of one or more materials among Al₂O₃, HfO₂, ZrO₂, HfZrO₄, TiO₂, Sc₂O₃, Y₂O₃, La₂O₃, Lu₂O₃, Nb₂O₅, and Ta₂O₅.

Each of the gate metal layers 234 and 244 may include a work function metal layer (WFM) formed on the high-k dielectric layer and a fill metal layer formed thereon, and depending on the case, may further include a cap metal layer formed on the fill metal layer.

The WFM may be a layer which determines an effective work function of each gate metal layer, and for example, may be formed of metal or a metal compound such as TiN, TiAlC, TiAlN, TiC, W, Ti, Ta, Mo, and Co.

In another embodiment of the present disclosure, because the p-type GAA-FET and the n-type GAA-FET have the same structure, like the embodiment of FIGS. 1 and 2, symmetry may be secured in electrical characteristic such as the threshold voltages Vt and current densities Ion and Ioff of two elements. Also, because the same gate structure is applied, effects such as process simplification, generalization of a mask pattern, and the enhancement of layout efficiency may be obtained.

Therefore, as described with reference to FIGS. 3 and 4, the static and dynamic symmetry of a logic circuit may be secured, thereby contributing to improve power efficiency and enhance an operation speed of a circuit. Accordingly, the complementary GAA-FET structure 200 according to another embodiment of the present disclosure may be formed in the horizontal direction unlike the vertical stack structure of FIGS. 1 and 2 but may maintain the same gate structure, and thus, may be technically characterized by securing a symmetrically electrical characteristic and enhancing process and design efficiency.

The GAA-FET structure according to the embodiments of the present disclosure described may be implemented with semiconductor packages of various types. For example, a semiconductor device according to embodiments of the present disclosure may be packaged as a type such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flat pack (TQFP), system in package (SIP), multi-chip package (MCP), wafer-level fabricated package (WFP), wafer-level processed stack package (WSP), and/or the like.

According to embodiments of the present disclosure, in a GAA-FET where an n-type GAA-FET and a p-type GAA-FET are arranged in a horizontal direction, or a complementary GAA-FET where the n-type GAA-FET and the p-type GAA-FET are stacked in a vertical direction, a gate structure of the n-type GAA-FET and a gate structure of the p-type GAA-FET (for example, a gate insulator structure and a gate metal structure) may be configured to be equal to each other, and thus, a process may be simplified, and a layout may be simplified, thereby improving mass productivity.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A complementary gate-all-around field effect transistor (GAA-FET) structure comprising:
a substrate;
a shallow trench isolation (STI) structure formed on the substrate; and
a pair of p-type GAA-FET and n-type GAA-FET stacked in a vertical direction in an active region defined by the STI structure,
wherein a gate metal layer of the p-type GAA-FET and a gate metal layer of the n-type GAA-FET have the same structure.

2. The complementary GAA-FET structure of claim 1, wherein the gate metal layer of the p-type GAA-FET and the gate metal layer of the n-type GAA-FET are formed by using the same material to have the same gate length and the same gate width.

3. The complementary GAA-FET structure of claim 1, wherein the gate metal layer of the p-type GAA-FET and the gate metal layer of the n-type GAA-FET are formed by using one or more of metals or metal compounds such as titanium nitride (TiN), titanium aluminum carbide (TiAlC), titanium aluminum nitride (TiAlN), titanium carbide (TiC), tungsten (W), titanium, (Ti), tantalum (Ta), molybdenum (Mo), and cobalt (Co).

4. The complementary GAA-FET structure of claim 1, wherein each of the p-type GAA-FET and the n-type GAA-FET comprises:
a plurality of semiconductor channel layers;
the gate metal layer surrounding a corresponding semiconductor channel layer among the plurality of semiconductor channel layers; and
a gate dielectric layer disposed between the corresponding semiconductor channel layer and the gate metal layer, and
the gate dielectric layer of the p-type GAA-FET and the gate dielectric layer of the n-type GAA-FET are formed in the same structure.

5. The complementary GAA-FET structure of claim 4, wherein the gate dielectric layer of the p-type GAA-FET and the gate dielectric layer of the n-type GAA-FET are formed by using the same material to have the same thickness.

6. The complementary GAA-FET structure of claim 4, wherein each of the gate dielectric layer of the p-type GAA-FET and the gate dielectric layer of the n-type GAA-FET comprises:
a silicon oxide layer surrounding a corresponding semiconductor channel layer; and
a high-k dielectric layer surrounding the silicon oxide layer.

7. The complementary GAA-FET structure of claim 6, wherein the high-k dielectric layer are formed by using one or more of aluminum oxide (Al₂O₃), hafnium oxide (HfO₂), zirconium oxide (ZrO₂), hafnium zirconium oxide (HfZrO₄), titanium oxide (TiO₂), scandium oxide (Sc₂O₃), yttrium oxide (Y₂O₃), lanthanum oxide (La₂O₃), lutetium oxide (Lu₂O₃), niobium oxide (Nb₂O₅), and tantalum oxide (Ta₂O₅).

8. The complementary GAA-FET structure of claim 1, further comprising another pair of p-type GAA-FET and n-type GAA-FET stacked in the vertical direction,
wherein gate structures of the other pair of p-type GAA-FET and n-type GAA-FET are formed to be equal to each other, and
gate structures of the pair of p-type GAA-FET and n-type GAA-FET and the gate structures of the other pair of p-type GAA-FET and n-type GAA-FET are formed to be different from each other.

9. A complementary gate-all-around field effect transistor (GAA-FET) structure comprising:
a substrate;
a shallow trench isolation (STI) structure formed on the substrate; and
a pair of p-type GAA-FET and n-type GAA-FET disposed in a horizontal direction in an active region defined by the STI structure,
wherein a gate metal layer of the p-type GAA-FET and a gate metal layer of the n-type GAA-FET have the same structure.

10. The complementary GAA-FET structure of claim 9, wherein the gate metal layer of the p-type GAA-FET and the gate metal layer of the n-type GAA-FET are formed by using the same material to have the same gate length and the same gate width.

11. The complementary GAA-FET structure of claim 9, wherein each of the p-type GAA-FET and the n-type GAA-FET comprises:
a plurality of semiconductor channel layers;
the gate metal layer surrounding a corresponding semiconductor channel layer among the plurality of semiconductor channel layers; and
a gate dielectric layer disposed between the corresponding semiconductor channel layer and the gate metal layer, and
the gate dielectric layer of the p-type GAA-FET and the gate dielectric layer of the n-type GAA-FET are formed in the same structure.

12. The complementary GAA-FET structure of claim 11, wherein the gate dielectric layer of the p-type GAA-FET and the gate dielectric layer of the n-type GAA-FET are formed by using the same material to have the same thickness.

13. The complementary GAA-FET structure of claim 11, wherein each of the gate dielectric layer of the p-type GAA-FET and the gate dielectric layer of the n-type GAA-FET comprises:
a silicon oxide layer surrounding a corresponding semiconductor channel layer; and
a high-k dielectric layer surrounding the silicon oxide layer.

14. The complementary GAA-FET structure of claim 9, further comprising another pair of p-type GAA-FET and n-type GAA-FET disposed in the horizontal direction,
wherein gate structures of the other pair of p-type GAA-FET and n-type GAA-FET are formed to be equal to each other, and
gate structures of the pair of p-type GAA-FET and n-type GAA-FET and the gate structures of the other pair of p-type GAA-FET and n-type GAA-FET are formed to be different from each other.
